(19) United States
(12) Patent Application Publication
(10) Pub. No.: US 2002/0113309 A1
(43) Pub. Date: Aug. 22, 2002

(54) Shielding of RF devices

(76) Inventor: Siamak Fazelpour, Irvine, CA (US)

Correspondence Address: SNELL & WILMER,L.L.P., One Arizona Center, 400 East Van Buren, Phoenix, AZ, 85004-2202, US

(21) Appl. No.: 09/754,585

(22) Filed: Jan. 4, 2001

(51) Int. Cl. H01L 21/44; H01L 21/48; H01L 21/50; H01L 23/34

(52) U.S. Cl. 257/728; 438/106; 438/121

(57) ABSTRACT

An apparatus and method for shielding devices from radiating electromagnetic (EM) waves. A chip having a plurality of conducting bumps, typically arranged in a row pattern, is herein provided. Using “flip-chip” techniques, as is common in the semiconductor industry, one or more of the conducting bumps can be reserved for shielding purposes. The wavelength of the radiating EM wave is determined and used to set the distance between the “shielding bumps” such that the distance is less than the wavelength. The device is shielded from the top by the reference net of the chip, from the bottom by the reference plane of the substrate, and from the sides by the invisible barrier created by the shielding bumps.

### FIELD OF THE INVENTION

The present invention relates, generally to, an apparatus and method for shielding RF (radio frequency) devices and, more particularly, to an apparatus and method for using flip chip bumps to prevent unwanted electromagnetic coupling with other RF devices.

### BACKGROUND OF THE INVENTION

The electric current flowing through a metallic device can create an electromagnetic (EM) field surrounding the device. Often the electromagnetic field produces unwanted “EMI” or electromagnetic interference. High frequency devices, such as RF (radio frequency) devices, typically include some form of shielding to prevent the radiating electromagnetic waves from coupling with other electronic devices.

A metal surface can provide a good barrier for electromagnetic waves. Depending on the frequency of the EM wave, and the thickness of the metal, it is possible to block the EM wave and have little or no wave propagation through the metal. Again, depending on the frequency of the EM wave the metal barrier is not required to be a continuous piece of metal, but rather may be a “mesh” pattern. For example, the metal mesh pattern can include openings spaced by a distance of approximately less than 75% of the wavelength (λ) of the EM wave. As is commonly known, the wave is rarely 100% blocked by the mesh; rather, after passing through the mesh, the wave attenuates very quickly. Thus, it is typical for a wave to be substantially blocked if the opening is less than about 75% of the wavelength of the traveling wave.

One technique for containing the radiating EM waves, e.g., emitting from a RF device, is to surround the radiating parts of the chip with a grounded metal can or a metal mesh. The metal barrier blocks or substantially blocks the EM waves and effectively prevents unwanted EM coupling with nearby devices.

A second technique for containing EM waves surrounds the use of a metal coated molding. Chips are often wire-bonded to a substrate. The wires are very thin (˜25 μ) and quite susceptible to damage, especially during transportation. To protect these wires, an epoxy-like substance is molded over the chip and substrate. The mold is then coated with a metal layer or metal mesh. Essentially, the metal around the molding provides a barrier for the radiating EM waves.

One problem associated with the foregoing prior art techniques relates to the high cost of these solutions. The addition of the previously described metal barriers increases the cost of fabrication of the device. In many cases, an inexpensive silicon-based device may significantly increase in cost due to the addition of an EMI metal barrier around the device. Moreover, the previous techniques consume valuable pcb (printed circuit board) space.

### SUMMARY OF THE INVENTION

This invention overcomes the problems outlined above and provides an apparatus and method for shielding RF (radio frequency) devices using flip chip bonding techniques.

In accordance with the invention, a chip having a plurality of bumps formed on the edge is provided. A small number of the bumps are reserved for “shielding purposes.” The spacing between the bumps, in accordance with the invention, provides an invisible EM barrier around the components of interest (e.g., the parts which emit EM waves, or alternatively, the parts which can be adversely affected by travelling EM waves). The shielding bumps and reference planes of both the chip and substrate provide an effective EM shield around the chip and substantially block EM waves from entering or leaving the shielded chip area.

### BRIEF DESCRIPTION OF THE DRAWINGS

These and other features, aspects and advantages of the present invention will become better understood with reference to the following description, appending claims, and accompanying drawings where:

FIGS. 1 and 2 illustrate, respectively, a top view and a cross sectional view of a prior art chip;

FIGS. 3 and 5 illustrate top views of chips in accordance with various embodiments of the present invention; and

FIGS. 4 and 6 illustrate cross sectional views of chips in accordance with various embodiments of the present invention.

### DETAILED DESCRIPTION OF EXEMPLARY EMBODIMENTS

The present invention relates to an improved apparatus and method for shielding electronic devices. In particular, the present invention relates to an improved apparatus and method for shielding devices that emit electromagnetic (EM) radiation. The present invention is conveniently described with reference to radio frequency (RF) devices; however, it should be appreciated that the apparatus and techniques herein described are useful for shielding all devices which either emit radiation or, alternatively, which may be adversely affected by radiation from nearby devices or similar sources of radiation.

In general there are two methodologies for bonding a chip to the underlying substrate: wire bonding and flip chip. In wire bonding, the chip is positioned atop a substrate with die attach. Corresponding bond pads on the substrate and on the chip are connected to one another via very thin wires (e.g., on the order of about 25 microns). The wire bonding process is performed sequentially (each pad is bonded one at a time in a sequential order) and requires additional fabrication time to carefully bond each of the wires. Furthermore, as the current flows through the wires from the substrate to the chip, an inductance is generated. The inductance may be in the range of about 1 to 5 nH. This unwanted inductance tends to flatten the rise and fall time of the signal. The high positive inductance, especially at high frequencies, is generally undesirable. Moreover, the thin wires are susceptible to damage and breakage which compromises chip performance.

To avoid the various problems with wire bonding, an alternate process for chip bonding is known as “flip chip.” In particular, several small metal bumps are formed on the top of the chip, e.g., in the range of 90 to 110 μ in width and 75 to 100 μ in height. The chip is then “flipped” so that the metal bumps are in contact with the metal bonds on the substrate. The metal-to-metal connections permit current flow between the substrate to the chip.

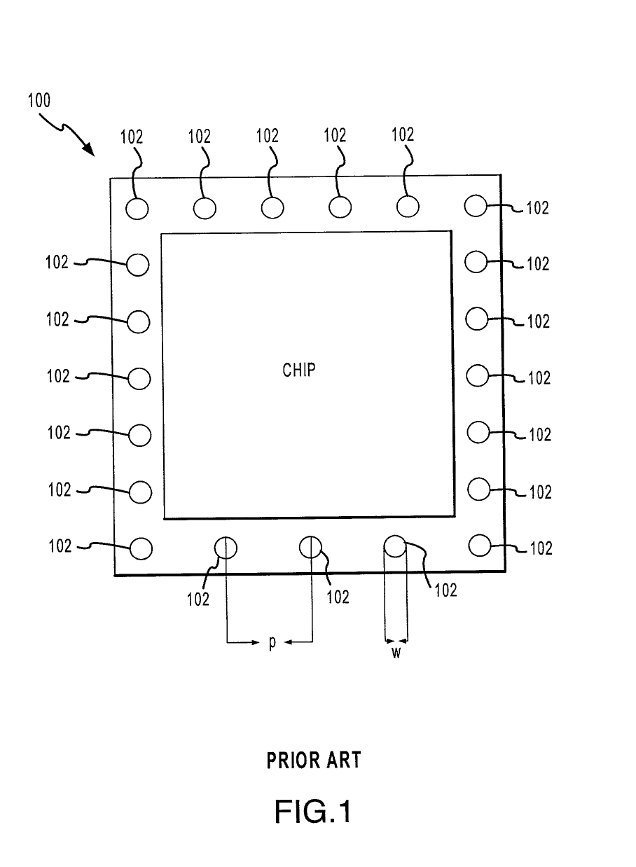

FIG. 1 illustrates a top view of a chip 100 of the prior art. A plurality of small metal bonds (“bumps”) 102 are formed at the periphery of the chip in a manner widely known in the semiconductor industry. Each bump 102 may include one or more layers of conducting material followed by a solder bump. The solder bump may be metal such as gold or it may be a composition of tin and lead, or the like. Bump 102 typically has a width (illustrated generally as “w”) of approximately 100 μ. The pitch (illustrated generally as “p”) is the distance from the mid point of one bump to the mid point of an adjacent bump. Currently, the minimum acceptable pitch in the industry is about 200 to 250 μ. Exemplary chip 100 is merely an illustrative representation and should not be construed as limiting.

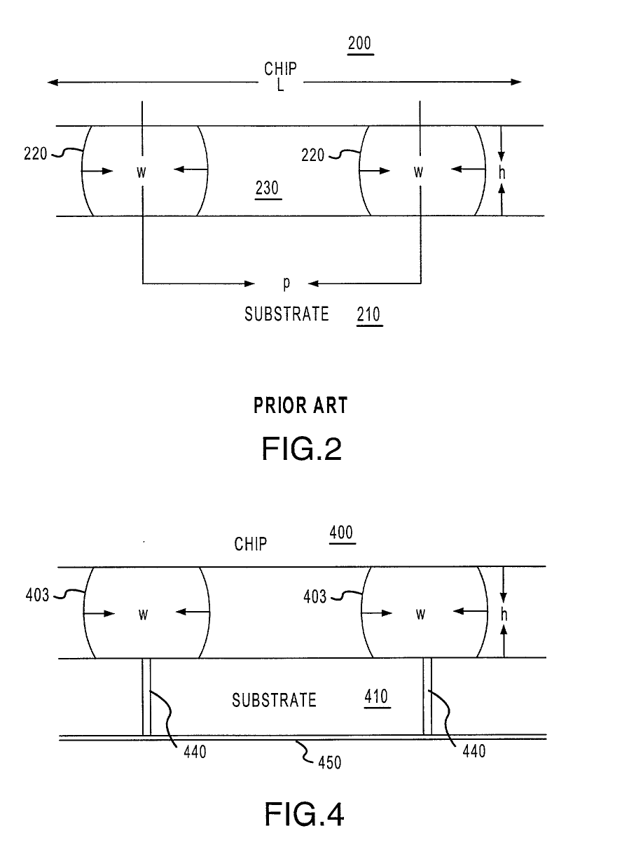

FIG. 2 illustrates a cross section of a flip chip configuration of the prior art. Chip 200 is “flipped over” so that the top of the chip faces substrate 210. A plurality of bumps 220 are formed at the periphery of chip 200 and are placed in contact with substrate 210. As previously mentioned, each bump 220 has a width (“w”) of approximately 100 μ and a height (illustrated generally as “h”) in the range of about 75 to 100 μ.

As is common with electrical devices during operation, the device may begin to produce heat. The chip has a certain thermal coefficient of expansion (TCE) which characterizes the extent to which the chip expands as it heats up. Chips typically have a TCE of around 3 ppm/° K (parts per million per degree Kelvin). As the temperature of the chip increases, the length of the chip (illustrated generally as “L”) increases proportionally (i.e., the chip expands) to a new length “ΔL.” The chip rate of expansion can be generally written as

$$( \frac{Δ L}{L} ≅ \frac{3 {e}^{- 6}}{{}^{∘} K} = 3 \frac{ppm}{{}^{∘} K} ) .$$

The substrate typically contains a high percentage of copper and will have a greater TCE than the chip, e.g., around 15 to 30 ppm/° K. Therefore, with each increase in temperature, the substrate expands five to ten times faster than the chip. The uneven rates of expansion between the chip and the substrate may cause the bond formed between any particular bump and the substrate to stretch and potentially disengage.

To help alleviate the problems with varying TCE, the area between two bumps is often filled with a dielectric material 230 (commonly referred to as “underfil”). The underfil is generally organic and has a dielectric constant of about 4 to 5. The dielectric constant of substrate 210 is compatible with the dielectric constant of underfil 230.

High frequency devices, such as RF devices, tend to emit electromagnetic (EM) radiation during normal operation. The EM radiation, often termed “EMI” (electromagnetic interference), is generally unwanted and can adversely interfere with nearby devices.

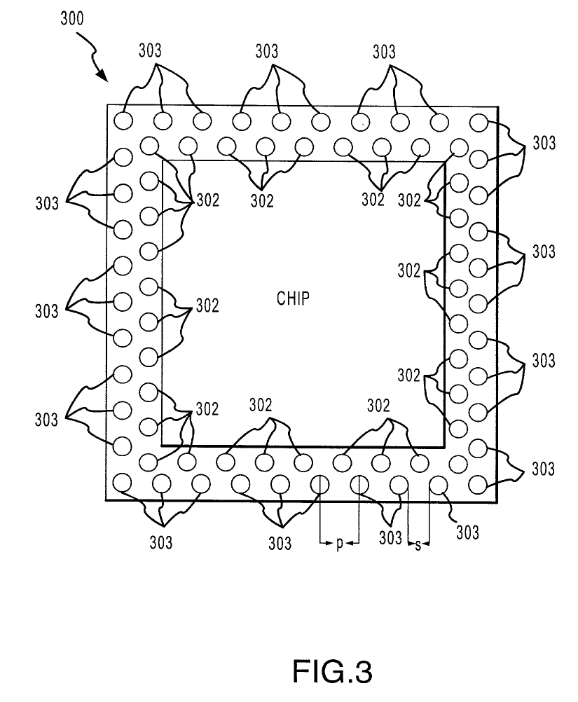

Referring now to FIG. 3, a chip structure 300 in accordance with the invention is illustrated. Chip 300 includes a plurality of bumps configured in a two-row pattern. For example, bumps 302 are arranged to form an inner row and bumps 303 are arranged to form an outer row or an outer-most periphery row. As illustrated, chip 300 includes two rows of bumps; however, it should be understood that any number of rows, in various configurations, are considered within the scope of the invention. The bumps are formed to comply with a predetermined design pitch (illustrated generally as “p”). Currently, the minimum acceptable design pitch in the industry is about 200 to 250 μ. Assuming each bump has a width of approximately 100 μ, the spacing (illustrated generally as “s”) between each of the bumps is approximately 100 μ. As previously discussed in the context of prior art chips 100 and 200, chip 300 is configured in a similar “flip chip” pattern. Chip 300 is “flipped over” so that the plurality of bumps 302, are in contact with the substrate.

Referring now to FIG. 4, a cross section of a flip chip configuration in accordance with the invention is illustrated. A chip 400 having a plurality of bumps 403 is configured to place bumps 403 in contact with a substrate 410, having a reference plane 450 and a plurality of vias 440. Substrate 410 may include any suitable Group IV semiconductor substrate known in the industry such as silicon, germanium, mixed silicon and germanium, mixed silicon and carbon, mixed silicon, germanium and carbon, and the like. Preferably substrate 410 is a wafer containing silicon as used in the semiconductor industry.

Substrate 410 further includes a reference plane 450. Reference plane 450 may be an internal layer of a suitable metal material or, alternatively, the reference plane may be a top metal layer of the substrate (not shown). Typically, if the reference plane is internal (for example as illustrated in FIG. 4), a plurality of vias 440 are suitably formed in substrate 410 to intra-connect bumps 403 to reference plane 450. Chip 400 may include a metal ring (not shown) intra-connecting the bumps 403 to a chip reference (not shown) (e.g., depending on the logic family, the reference may be ground). The RF input and output pads of the device are typically located within the ring. Current flows through the metal of the chip and connects the chip to the outside substrate and beyond.

Referring again to FIG. 3, in one embodiment of the invention, row of bumps 302 may be used for high speed (critical) and other digital/analog signals. Row of bumps 303 may be reserved for “shielding” purposes of the device.

“Shielding” is herein defined to include blocking, protecting, guarding, safeguarding, restraining, containing, and the like, a shielded device from radiating EM waves.

The pitch (“p”) of bumps 303 is preferably less than about 75% of the wavelength of the highest frequency content of an RF signal at or near the device. If the pitch lies in the preferred range, then the spacing (“s”) between the bumps will also be less than about 75% of the wavelength of the highest frequency content of the RF signal. A spacing in the preferred range causes the emerging signal to attenuate rapidly. While it is understood that 100% blockage of the wave is typically not practical or necessary, depending upon the spacing through which the wave emerges, the wave will often attenuate to a sufficient degree to satisfactorily reduce or eliminate EMI. By substantially blocking the unwanted emitted signals, chip 300 effectively shields radiating EM waves. Alternatively, if the spacing is such that a wave traveling towards chip 300 is substantially blocked, then the chip may be adequately shielded from traveling EM waves. Thus, the chip is shielded from the top by the chip reference plane, from the bottom by the reference plane of the substrate, and from the sides by one or more bumps 303 in accordance with the invention.

The spacing between bumps 303 may be calculated based on the parameters described herein. One possible set of calculations for determining a suitable spacing is discussed below; however, it should be appreciated that there may be other techniques, methods, and calculations for determining the spacing which are within the scope of the invention.

Spacing (s) may be defined as:

s=p−w (1)

where p is the pitch and w is the width of a bump.

As previously mentioned, the width of the bumps are generally held to about 100 μ. Although the width can expand slightly due to TOE (thermal coefficient expansion), as previously explained, it is often desirable to deposit underfil in the area between two bumps to lessen this effect.

The pitch, as previously defined, is the distance between the mid point of one bump to the mid point of an adjacent bump, Currently, industry standards limit the distance to a minimum of about 200 to 250 μ. The pitch may also be limited due to various mechanical constraints. For example, a minimum spacing may be desired to facilitate the flow of underfil through the bumps, or if the solderpad on the substrate is “solder-mask” defined, then the registration tolerance of the solder-mask may substantially dictate the pitch limit. However, as will be demonstrated below, it is not essential that the minimum pitch be employed in all applications.

The RF signals (and radiating EM waves) of particular interest in the context of the invention are in the range of about 800 to 2500 MHz or 0.8 to 2.5 GHz, with the range of most interest from about 1 to 2.5 GHz.

As is known, the wavelength (λ) is proportional to the frequency and is generally given by:

$$λ = \frac{c}{f} \qquad ( 2 )$$

where c=3×10⁸ m/s (velocity of waves in a vacuum) and f is the frequency of the wave in hertz (s⁻¹).

Further, as is known, the wavelength is proportional to the dielectric constant of the medium through which the wave is travelling. Thus, Equation 2 can be rewritten as follows:

$$λ = \frac{c}{f \sqrt{{ϵ}_{r}}} = \frac{{λ}_{0}}{\sqrt{{ϵ}_{r}}} \qquad ( 3 )$$

where λ₀ is the free-space wavelength and εᵣ is the dielectric constant.

Dry air at room temperature has a dielectric constant of 1.0. A typical organic semiconductor substrate may have a dielectric constant of about 4 to 5. As discussed, the spacing between two bumps is an area of importance (i.e., in regions where EM waves can enter or escape the boundaries of the chip). Underfil is commonly deposited in this area (between two adjacent bumps) and typically has a dielectric constant compatible with the substrate.

Thus, assuming underfil is deposited in the spacing and the underfil has a dielectric constant of 4, Equation 3 becomes:

$$λ = \frac{c}{f \sqrt{4}} = \frac{{λ}_{0}}{2} \qquad ( 4 )$$

Using Equation 4, at a frequency (f) of 2.5 GHz, the wavelength of a traveling wave is about 6 cm. Thus, if the spacing between two bumps is less than about 75% of 6 cm (i.e., if the spacing is about 4.5 cm), waves which pass through the spacing will be significantly attenuated. This approach, however, leaves very little margin for error. To account for possible errors and the like, the spacing should be less than one fifth to one twentieth of the calculated wavelength (i.e., λ/5 to λ/20). Applying the error factor of one twentieth (1/20), a suitable spacing to substantially block a 2.5 GHz travelling wave would be in the range of about 3 mm (or 3000 μ).

As previously mentioned, the minimum pitch is about 200 to 250 μ and the width of the bump is approximately 100 μ. Using Equation 1 the spacing would be 100 to 150 μ. As is clear, at the highest frequency of most interest (2.5 GHz) the suitable spacing is nearly thirty times smaller than needed to substantially block the wave. Using the above Equations, at a frequency of 1 GHz, a suitable spacing to substantially block the wave is 7.5 mm (or 7500 μ), roughly 75 times smaller than needed.

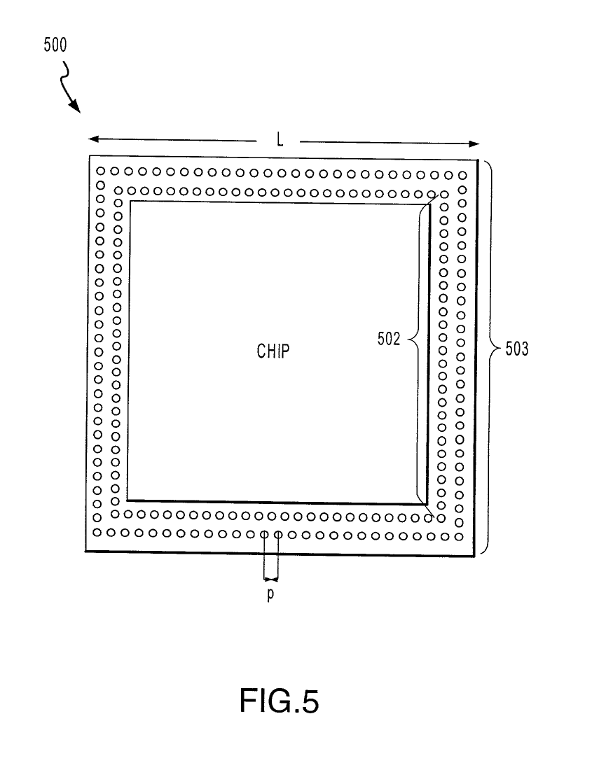

Referring now to FIG. 5, an exemplary chip 500 in accordance with the invention is illustrated. Chip 500 is similar to chip 300 and includes a plurality of bumps 502 and 503 formed to include two rows. Bumps 503 are located at the periphery of chip 500 and can be reserved for shielding purposes. Chip 500 has a length (illustrated generally as “l”) which may vary depending on the application. In the illustrated embodiment, chip 500 has a length of 10 mm (or 10,000μ) which is typical of a chip size in the industry. Chip 500 further exhibits a pitch (illustrated generally as “p”) between bumps 503. Assuming for this example that the pitch is 250 μ, the maximum number of bumps that can fit on one length of the chip is 40 (10,000 μ/250 μ). Further assuming for this example that the signal frequency is 2.5 GHz, from the above calculations, a suitable spacing to substantially block a travelling wave is 3 mm (or 3000 μ). Thus, for every 3 mm, one of the bumps 503 may be reserved for shielding.

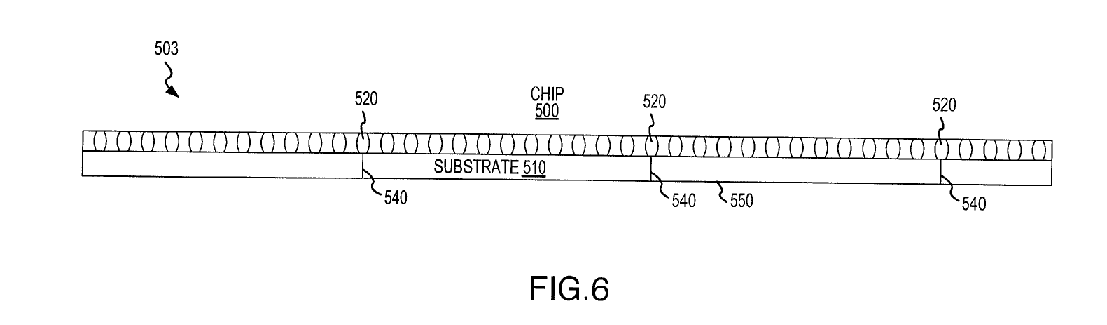

Referring now to FIG. 6, a cross section of the exemplary embodiment of chip 500 is illustrated. Chip 500 is flipped over to place bumps 503 in contact with a substrate 510. Bumps 503 include three bumps 520 separated by a distance of approximately 3 mm. A plurality of vias 540 intra-connects bumps 520 to a reference plane 550 of substrate 510. A suitable underfil is deposited in the spacing between each of the bumps 503 and preferably has a dielectric constant compatible with the dielectric constant of substrate 510.

In the embodiment illustrated in FIG. 6, chip 500 has a length of about 10 mm and 40 bumps 503 are equally spaced along one side of the chip. Choosing a signal frequency of 2.5 GHz and an underfil having a dielectric constant of about 4, bumps 520 may be advantageously used for shielding chip 500. Chip 500 is configured to include EM shielding on the top by a chip reference (not shown), on the bottom by reference plane 550 (or alternatively, the reference may be the top metal layer of substrate 510 (not shown)), and on the sides by the barrier created by bumps 520. The present embodiment is configured such that electromagnetic waves having a wavelength greater than 3 mm are substantially blocked through the sides. Vias 540 do not pose an escape problem because their size is much less than about 75% of the wavelength of the EM wave. Aside from the three bumps 520, the remaining bumps 503 could be used for non-emitting purposes, such as digital or low frequency applications.

In another aspect of the invention, a chip may include multiple rows of bumps, for example two or more rows. The inner most row may be used for high frequency signal transfer and may emit EM radiation. The middle row could be reserved for shielding purposes in a manner similar to those previously described for chips 300, 400 and 500. The outer most row (periphery) may be used for non-emitting purposes such as digital and low frequency applications. One skilled in the art will readily recognize that any number of rows having any number of bumps may be included in the present invention. Furthermore, the row reserved for “shielding” purposes is not limited to the outer most row, but rather may include a small number of bumps in any of the rows. However, it should be appreciated that regardless of the particular configuration of the row design on the chip, to effectively shield the chip, high frequency radiating parts of the chip should be inside the invisible barrier created by the bumps reserved for shielding.

The present invention has been described above with reference to exemplary embodiments. Those skilled in the art having read this disclosure will recognize that changes and modifications may be made to the disclosed embodiments without departing from the scope of the present invention. For example, the present invention offers shielding for chips operating at frequencies beyond those disclosed, e.g., up to 10 GHz. In addition, the chip size is variable and the number of bumps and row configuration may be modified depending upon the particular application. Moreover, the underfil material may be a different dielectric constant than that of the associated substrate. One of skill in the art can readily recognize that various other calculations, equations, variables, and the like can be made without departing from the spirit of the present invention. These and other changes or modifications are intended to be included within the scope of the present invention, as expressed in the following claims.

1. A method of shielding a chip from unwanted electromagnetic radiation comprising the steps of:
providing a chip having a plurality of conducting bumps coupled to a chip reference;
forming a contact area between the bumps and a semiconductor substrate;
determining a distance such that an electromagnetic wave is substantially blocked through the contact area; and
coupling at least one of the bumps to a reference plane of the substrate in accordance with the determining step.

2. The method of claim 1 wherein the coupling step comprises providing a plurality of vias to couple the bumps to an inner reference plane of the substrate.

3. The method of claim 2 wherein the coupling step comprises coupling the bumps to a metal layer.

4. The method of claim 1 wherein the providing step comprises providing a chip comprising two rows of conducting bumps.

5. The method of claim 4 further comprising the step of reserving one of the rows for shielding purposes.

6. The method of claim 1 wherein forming the contact area comprises:
forming points of contact at the bumps and the substrate; and
forming a predetermined spacing between adjacent bumps.

7. The method of claim 6 further comprising the step of depositing a filler in the spacing.

8. The method of claim 1 wherein the determining step comprises:
determining a wavelength of an electromagnetic wave; and
determining a spacing between two bumps to substantially block the electromagnetic wave.

9. An electronic device comprising:
a semiconductor substrate having a reference plane;
a chip having a plurality of conducting bumps in communication with a reference of the chip;
at least one contact point between the bumps and the substrate; and
a spacing between at least one of the contact points, the spacing being predetermined such that an unwanted wave radiating near the device is substantially blocked.

10. The device of claim 9 further comprising a vias connecting the contact point with the reference plane of the semiconductor substrate.

11. The device of claim 10 wherein the reference plane of the semiconductor substrate comprises an inner metal layer.

12. The device of claim 9 wherein the reference plane of the semiconductor substrate comprises a top metal layer.

13. The device of claim 9 wherein the conducting bumps comprise a plurality of shielding bumps and a plurality of non-shielding bumps.

14. The device of claim 13 wherein the spacing defines a distance between two shielding bumps and encompasses at least one non-shielding bump.

15. The device of claim 13 wherein the bumps comprise two or more rows of bumps.

16. The device of claim 15 wherein at least one row of bumps includes both shielding bumps and non-shielding bumps.

17. The device of claim 16 wherein the shielding bumps are determined in accordance with the spacing.

18. A method for preventing unwanted electromagnetic coupling of a high frequency electronic device of the type including a top plane, a bottom plane and a side plane, the method comprising the step of:
forming a shield encompassing the device, the shield being defined by the top plane, the bottom plane and the side plane, the side plane being formed by separating a plurality of conducting bumps by a predetermined distance, the distance being less than a wavelength of a radiating electromagnetic wave.

19. The method of claim 18 wherein the high frequency device comprises a radio frequency device having a semiconductor chip and a semiconductor substrate.

20. The method of claim 19 wherein the step of forming the shield further comprises:
defining the top plane by a chip reference net, the reference net being electrically coupled to the bumps; and
defining the bottom plane by a substrate reference, the substrate reference electrically coupled to the bumps.

21. The method of claim 19 wherein the step of forming the side plane further comprises:
placing the bumps in contact with the substrate; and
coupling the bumps with the bottom plane.

22. The method of claim 21 wherein the step of coupling the bumps comprises disposing a plurality of vias in the substrate.

23. The method of claim 22 wherein the bottom plane comprises a metal inner layer.

24. The method of claim 18 wherein the plurality of conducting bumps comprises both shielding bumps and non-shielding bumps.

25. The method of claim 18, wherein the distance is in the range from one fifth to one twentieth of the wavelength of the wave.

26. An electronic device comprising:
signal shielding means in a semiconductor substrate;
signal shielding means in a chip coupled to a plurality of conducting bumps;
a plurality of electrical contact points between the substrate and the bumps, the contact points forming at least two rows at the periphery of the device; and
spacing means between the contact points of at least one of the rows, the spacing means configured to substantially block electromagnetic interference.
